(19) United States
(12) Patent Application Publication
(10) Pub. No.: US 2024/0250643 A1
(43) Pub. Date: Jul. 25, 2024

(54) DOHERTY AMPLIFIER

(71) Applicant: Murata Manufacturing Co., Ltd., Kyoto (JP)

(72) Inventor: Shohei IMAI, Kyoto (JP)

(21) Appl. No.: 18/405,476

(22) Filed: Jan. 5, 2024

(30) Foreign Application Priority Data
Jan. 20, 2023 (JP) 2023-007192

(51) Int. Cl. H03F 1/02; H03F 3/21

(52) U.S. Cl. CPC H03F 1/0288; H03F 3/211

(57) ABSTRACT

A Doherty amplifier includes: a carrier amplifier that is formed on a semiconductor substrate and that includes amplifiers in one or more stages including a first amplifier in one stage to which a first bias current is inputted; a peak amplifier that is formed on the semiconductor substrate and that includes amplifiers in two or more stages including a second amplifier to which a second bias current smaller than the first bias current is inputted; and a first resistor that is inserted in series into a power supply path to the second amplifier.

### CROSS REFERENCE TO RELATED APPLICATION

This application claims priority from Japanese Patent Application No. 2023-007192 filed on Jan. 20, 2023. The content of this application is incorporated herein by reference in its entirety.

### BACKGROUND OF THE DISCLOSURE

### 1. Field of the Disclosure

The present disclosure relates to a Doherty amplifier.

### 2. Description of the Related Art

U.S. patent Ser. No. 10/110,183 describes a Doherty amplifier that includes a carrier amplifier and a peak amplifier each including amplifiers in three stages. In this Doherty amplifier, power is supplied to the collector of the transistor in the first-stage amplifier in each of the carrier amplifier and the peak amplifier from a power supply terminal through an inductor.

### BRIEF SUMMARY OF THE DISCLOSURE

When the Doherty amplifier described in U.S. patent Ser. No. 10/110,183 is formed on one semiconductor substrate, the power supply terminal on the semiconductor substrate is connected with a finite inductance interposed, and therefore, a sufficiently low impedance is not attained and the power supply terminal has an AC amplitude due to a leaking signal leaking from the carrier amplifier. This does not become a problem in general amplifiers. However, this becomes a problem in the Doherty amplifier when the bias point of the first-stage amplifier in the carrier amplifier and the bias point of the first-stage amplifier in the peak amplifier are different.

Specifically, the Doherty amplifier is a technique for attaining a high efficiency without operating the peak amplifier to the extent possible by biasing the peak amplifier so as to prevent the bias current from flowing. That is, the bias point of the first-stage amplifier in the carrier amplifier and the bias point of the first-stage amplifier in the peak amplifier are made different in order to control the operation of the peak amplifier. However, the power supply terminal on the semiconductor substrate has an AC amplitude as described above, which results in driving the posterior amplifier in the peak amplifier through the inductor through which power is supplied to the first-stage amplifier in the peak amplifier. That is, even when an attempt to control the operation of the peak amplifier is made by lowering the bias point of the first-stage amplifier in the peak amplifier, an event can occur in which a leaking signal leaking through the power supply terminal, which is a leak path, drives the posterior amplifier in the peak amplifier and the Doherty amplifier malfunctions.

The present disclosure has been made in view of the above-described problem and a possible benefit thereof is to reduce the likelihood that the peak amplifier malfunctions.

According to one aspect of the present disclosure, a Doherty amplifier includes: a carrier amplifier that is formed on a semiconductor substrate and that includes amplifiers in one or more stages including a first amplifier in one stage to which a first bias current is inputted; a peak amplifier that is formed on the semiconductor substrate and that includes amplifiers in two or more stages including a second amplifier to which a second bias current smaller than the first bias current is inputted; and a first resistor that is inserted in series into a power supply path to the second amplifier.

According to the present disclosure, the likelihood that the peak amplifier malfunctions can be reduced.

### BRIEF DESCRIPTION OF THE SEVERAL VIEWS OF THE DRAWINGS

FIG. 1 is a diagram illustrating a configuration of an amplifier module of a first embodiment;

FIG. 2 is a diagram illustrating a part of a peak amplifier in a semiconductor device of the first embodiment;

FIG. 3 is a diagram illustrating a configuration of an amplifier module of a second embodiment; and

FIG. 4 is a diagram illustrating a configuration of an amplifier module of a third embodiment.

### DETAILED DESCRIPTION OF THE DISCLOSURE

Hereinafter, embodiments of the present disclosure will be described in detail with reference to the drawings. Note that the embodiments are not intended to limit the present disclosure. Each embodiment is illustrative and configurations described in different embodiments can be partially replaced or combined as a matter of course. In second and subsequent embodiments, a description of a matter common to a first embodiment will be omitted and only differences will be described. Specifically, similar effects attained by similar configurations will not be mentioned one by one in each embodiment.

### First Embodiment

### Configuration

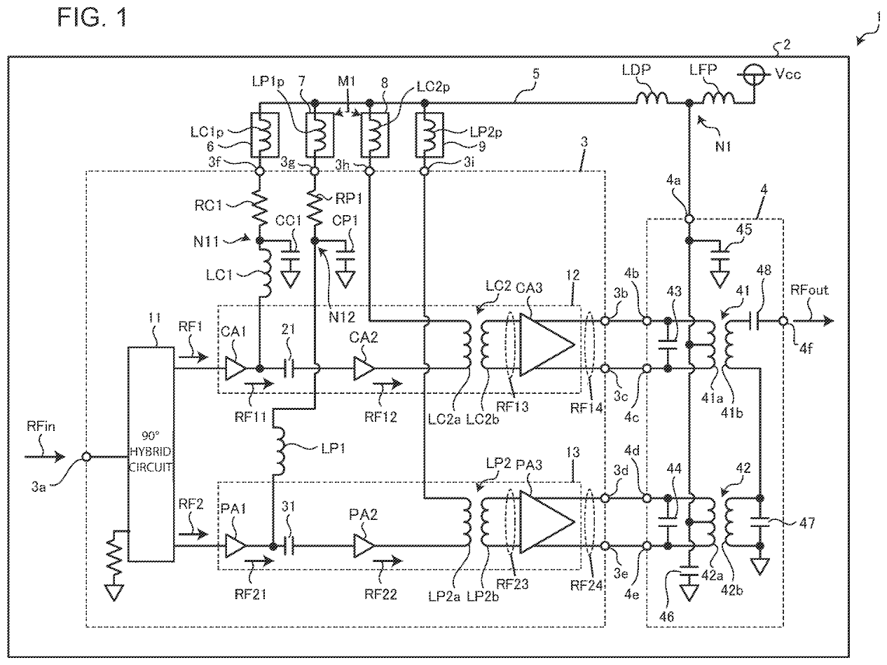

FIG. 1 is a diagram illustrating a configuration of an amplifier module of the first embodiment.

An amplifier module 1 includes a substrate 2, and a semiconductor device 3 and a combiner 4 mounted on the substrate 2.

The semiconductor device 3 is a Doherty amplifier. The semiconductor device 3 includes a 90° hybrid circuit 11, a carrier amplifier 12, a peak amplifier 13, inductors LC1 and LP1, capacitors CC1 and CP1, and resistors RC1 and RP1, which are formed on one semiconductor substrate.

The semiconductor device 3 has a terminal 3a to which a radio-frequency input signal RFin is inputted.

The 90° hybrid circuit 11 is electrically connected between the terminal 3a and the carrier amplifier 12 and between the terminal 3a and the peak amplifier 13.

In response to the input of the radio-frequency input signal RFin, the 90° hybrid circuit 11 outputs radio-frequency signals RF1 and RF2 having phases different from each other by approximately 90° to the carrier amplifier 12 and the peak amplifier 13, respectively. Note that “approximately 90°” includes not only a phase of 90° but also phases of 90°±45°.

The carrier amplifier 12 includes cascade-connected amplifiers CA1, CA2, and CA3, a capacitor 21, and a balun LC2.

Although the carrier amplifier 12 includes the amplifiers in three stages in the first embodiment, the present disclosure is not limited to this. The carrier amplifier 12 may include amplifiers in one or more stages.

The amplifier CA1 corresponds to an example of “first amplifier” of the present disclosure. The amplifier CA2 corresponds to an example of “fourth amplifier” of the present disclosure.

The input terminal of the amplifier CA1 (the base or gate of the transistor) is electrically connected to the 90° hybrid circuit 11. The output terminal of the amplifier CA1 (the collector or drain of the transistor) is electrically connected to one end of the capacitor 21.

To the collector or drain of the transistor in the amplifier CA1, power is supplied through the inductor LC1.

One end of the inductor LC1 is electrically connected to the collector or drain of the transistor in the amplifier CA1. The other end of the inductor LC1 is electrically connected to a node N11. One end of the capacitor CC1 is electrically connected to the node N11. The other end of the capacitor CC1 is electrically connected to a reference potential. Although the reference potential is, for example, a ground potential, the present disclosure is not limited to this. One end of the resistor RC1 is electrically connected to the node N11. The other end of the resistor RC1 is electrically connected to a terminal 3f of the semiconductor device 3.

Although the resistor RC1 is formed of, for example, a material having a resistivity higher than that of the material of wiring lines inside the semiconductor device 3, the present disclosure is not limited to this. The resistor RC1 may be formed of a material that is the same as the material of the wiring lines inside the semiconductor device 3 and may have a line width narrower than that of the wiring lines inside the semiconductor device 3. The resistor RC1 may be formed of a material that is the same as the material of the wiring lines inside the semiconductor device 3 and may have a film thickness thinner than that of the wiring lines inside the semiconductor device 3.

To the terminal 3f of the semiconductor device 3, a supply voltage Vcc is supplied through a wiring line 5 on the substrate 2. The wiring line 5 has parasitic inductances LDP and LFP. The wiring line 5 and the terminal 3f are electrically connected by an interface member 6 interposed therebetween. Although the interface member 6 is, for example, a wire or a bump, the present disclosure is not limited to this. The interface member 6 has a parasitic inductance LC1p.

The amplifier CA1 amplifies the radio-frequency signal RF1 and outputs a radio-frequency signal RF11 obtained as a result of the amplification to the one end of the capacitor 21.

The other end of the capacitor 21 is electrically connected to the input terminal of the amplifier CA2. The capacitor 21 removes the DC component of the radio-frequency signal RF11 and outputs the radio-frequency signal RF11 to the input terminal of the amplifier CA2. That is, the capacitor 21 is a DC cut capacitor.

The output terminal of the amplifier CA2 is electrically connected to one end of a primary winding LC2a of the balun LC2. To the other end of the primary winding LC2a of the balun LC2, power is supplied through a terminal 3h of the semiconductor device 3.

To the terminal 3h of the semiconductor device 3, the supply voltage Vcc is supplied through the wiring line 5 on the substrate 2. The wiring line 5 and the terminal 3h are electrically connected by an interface member 8 interposed therebetween. Although the interface member 8 is, for example, a wire or a bump, the present disclosure is not limited to this. The interface member 8 has a parasitic inductance LC2p.

Both ends of a secondary winding LC2b of the balun LC2 are electrically connected to two input terminals of the amplifier CA3, which is a differential amplifier, respectively.

Although the amplifier CA3 is a differential amplifier in the first embodiment, the present disclosure is not limited to this. The amplifier CA3 may be a single-end amplifier. When the amplifier CA3 is a single-end amplifier, the balun LC2 is not necessary.

The balun LC2 converts a radio-frequency signal RF12 to a radio-frequency signal RF13, which is a differential signal, and outputs the radio-frequency signal RF13 obtained as a result of the conversion to the two input terminals of the amplifier CA3.

Two output terminals of the amplifier CA3 are electrically connected to terminals 3b and 3c of the semiconductor device 3, respectively.

The amplifier CA3 amplifies the radio-frequency signal RF13, which is a differential signal, and outputs a radio-frequency signal RF14, which is a differential signal obtained as a result of the amplification, to the terminals 3b and 3c.

The peak amplifier 13 includes cascade-connected amplifiers PA1, PA2, and PA3, a capacitor 31, and a balun LP2.

Although the peak amplifier 13 includes the amplifiers in three stages in the first embodiment, the present disclosure is not limited to this. The peak amplifier 13 may include amplifiers in two or more stages.

The amplifier PA1 corresponds to an example of “second amplifier” of the present disclosure. The amplifier PA2 corresponds to an example of “third amplifier” of the present disclosure.

It is assumed that when no signal is inputted, an idle current set by a base (or gate) bias inputted to the amplifier PA1 is smaller than an idle current set for the amplifier CA1. It is assumed that an idle current set for the amplifier PA2 is larger than the idle current set for the amplifier PA1. It is assumed that the idle current set for the amplifier PA2 is equal to an idle current set for the amplifier CA2. It is assumed that the idle current set for the amplifier CA1 is equal to the idle current set for the amplifier CA2. However, the present disclosure is not limited to these. Note that the idle currents are compared here by normalization based on the unit transistor size. In the specification, it is assumed that when the magnitudes of the amounts of idle currents are compared, the magnitudes of the amounts of idle currents when no signal is inputted are compared. In the specification, it is further assumed that a state in which currents are equal includes variations of ±10% by taking into consideration individual differences between transistors, resistors, capacitors, and so on.

The input terminal of the amplifier PA1 is electrically connected to the 90° hybrid circuit 11. The output terminal of the amplifier PA1 is electrically connected to one end of the capacitor 31.

To the collector or drain of the transistor in the amplifier PA1, power is supplied through the inductor LP1.

One end of the inductor LP1 is electrically connected to the collector or drain of the transistor in the amplifier PA1. The other end of the inductor LP1 is electrically connected to a node N12. One end of the capacitor CP1 is electrically connected to the node N12. The other end of the capacitor CP1 is electrically connected to the reference potential. One end of the resistor RP1 is electrically connected to the node N12. The other end of the resistor RP1 is electrically connected to a terminal 3g of the semiconductor device 3.

The resistor RP1 corresponds to an example of “first resistor” of the present disclosure. The capacitor CP1 corresponds to an example of “first capacitor” of the present disclosure. The inductor LP1 corresponds to an example of “first inductor” of the present disclosure. A path for supplying the external supply voltage Vcc to an amplifier corresponds to “power supply path” of the present disclosure.

Although the resistor RP1 is formed of, for example, a material having a resistivity higher than that of the material of the wiring lines inside the semiconductor device 3, the present disclosure is not limited to this. The resistor RP1 may be formed of a material that is the same as the material of the wiring lines inside the semiconductor device 3 and may have a line width narrower than that of the wiring lines inside the semiconductor device 3. The resistor RP1 may be formed of a material that is the same as the material of the wiring lines inside the semiconductor device 3 and may have a film thickness thinner than that of the wiring lines inside the semiconductor device 3.

To the terminal 3g of the semiconductor device 3, the supply voltage Vcc is supplied through the wiring line 5 on the substrate 2. The wiring line 5 and the terminal 3g are electrically connected by an interface member 7 interposed therebetween. Although the interface member 7 is, for example, a wire or a bump, the present disclosure is not limited to this. The interface member 7 has a parasitic inductance LP1p.

The amplifier PA1 amplifies the radio-frequency signal RF2 and outputs a radio-frequency signal RF21 obtained as a result of the amplification to the one end of the capacitor 31.

The other end of the capacitor 31 is electrically connected to the input terminal of the amplifier PA2. The capacitor 31 removes the DC component of the radio-frequency signal RF21 and outputs the radio-frequency signal RF21 to the input terminal of the amplifier PA2. That is, the capacitor 31 is a DC cut capacitor.

The output terminal of the amplifier PA2 is electrically connected to one end of a primary winding LP2a of the balun LP2. To the other end of the primary winding LP2a of the balun LP2, power is supplied through a terminal 3i of the semiconductor device 3.

To the terminal 3i of the semiconductor device 3, the supply voltage Vcc is supplied through the wiring line 5 on the substrate 2. The wiring line 5 and the terminal 3i are electrically connected by an interface member 9 interposed therebetween. Although the interface member 9 is, for example, a wire or a bump, the present disclosure is not limited to this. The interface member 9 has a parasitic inductance LP2p.

Both ends of a secondary winding LP2b of the balun LP2 are electrically connected to two input terminals of the amplifier PA3, which is a differential amplifier, respectively.

Although the amplifier PA3 is a differential amplifier in the first embodiment, the present disclosure is not limited to this. The amplifier PA3 may be a single-end amplifier. When the amplifier PA3 is a single-end amplifier, the balun LP2 is not necessary.

The balun LP2 converts a radio-frequency signal RF22 to a radio-frequency signal RF23, which is a differential signal, and outputs the radio-frequency signal RF23 obtained as a result of the conversion to the two input terminals of the amplifier PA3.

Two output terminals of the amplifier PA3 are electrically connected to terminals 3d and 3e of the semiconductor device 3, respectively.

The amplifier PA3 amplifies the radio-frequency signal RF23, which is a differential signal, and outputs a radio-frequency signal RF24, which is a differential signal obtained as a result of the amplification, to the terminals 3d and 3e.

The combiner 4 includes baluns 41 and 42 and capacitors 43, 44, 45, 46, 47, and 48.

The combiner 4 has terminals 4b and 4c that are electrically connected to the terminals 3b and 3c of the semiconductor device 3, respectively. To the terminals 4b and 4c, the radio-frequency signal RF14 is inputted.

Both ends of a primary winding 41a of the balun 41 are electrically connected to the terminals 4b and 4c of the combiner 4, respectively. The capacitor 43 is electrically connected in parallel to the primary winding 41a of the balun 41.

The combiner 4 has terminals 4d and 4e that are electrically connected to the terminals 3d and 3e of the semiconductor device 3, respectively. To the terminals 4d and 4e, the radio-frequency signal RF24 is inputted.

Both ends of a primary winding 42a of the balun 42 are electrically connected to the terminals 4d and 4e of the combiner 4, respectively. The capacitor 44 is electrically connected in parallel to the primary winding 42a of the balun 42.

The midtap of the primary winding 41a of the balun 41 and the midtap of the primary winding 42a of the balun 42 are electrically connected to a terminal 4a of the combiner 4. The terminal 4a is electrically connected to a node N1 between the parasitic inductance LDP and the parasitic inductance LFP. To the midtap of the primary winding 41a of the balun 41 and the midtap of the primary winding 42a of the balun 42, the supply voltage Vcc is supplied.

One end of the capacitor 45 is electrically connected to a point between the midtap of the primary winding 41a of the balun 41 and the terminal 4a of the combiner 4. The other end of the capacitor 45 is electrically connected to the reference potential.

One end of the capacitor 46 is electrically connected to the midtap of the primary winding 42a of the balun 42. The other end of the capacitor 46 is electrically connected to the reference potential.

The capacitor 47 is electrically connected in parallel to a secondary winding 42b of the balun 42. One end of the secondary winding 42b of the balun 42 is electrically connected to the reference potential. The other end of the secondary winding 42b of the balun 42 is electrically connected to one end of a secondary winding 41b of the balun 41. The other end of the secondary winding 41b of the balun 41 is electrically connected to one end of the capacitor 48. The other end of the capacitor 48 is electrically connected to a terminal 4f of the combiner 4.

The combiner 4 combines the radio-frequency signal RF14 and the radio-frequency signal RF24 and outputs a single-end radio-frequency output signal RFout.

### Influences of Parasitic Inductances

The peak amplifier 13 that malfunctions due to the parasitic inductances LP1p and LC2p when the resistor RP1 is not provided will be described. Although specific figures close to those in an actual operation will be used to describe a circuit operation, the present disclosure is not limited to this.

Each of the amplifier CA1 and the amplifier CA2 is biased so as to allow a bias (base or gate bias) current to flow and has a gain. A gain per amplifier in one stage is, for example, 10 dB. The sum of the gain of the amplifier CA1 and the gain of the amplifier CA2 are equal to 20 dB in total.

It is assumed that when the radio-frequency signal RF2 is a small signal or there is no signal, a bias (base or gate bias) current smaller than the bias current for the amplifier CA1 is set for the amplifier PA1, and the amplifier PA1 has a gain of −30 dB.

As described above, it is assumed that the bias (base or gate bias) current for the amplifier PA2 is equal to the bias (base or gate bias) current for the amplifier CA2. Therefore, the amplifier PA2 has a gain of 10 dB similarly to the amplifier CA2.

The die size of the semiconductor device 3 is small, and the interface member 7 and the interface member 8 are unable to be disposed so as to be sufficiently spaced apart from each other. Therefore, the parasitic inductance LP1p and the parasitic inductance LC2p are magnetically coupled and have a slight mutual inductance M1. A case where the mutual inductance M1 causes leaking of a signal of −30 dB will be considered.

When magnetic coupling does not occur, the power of the radio-frequency signal RF22 outputted from the amplifier PA2 is as follows.

$$- 30 dB ( gain of amplifier PA 1 )$$

$$+ 10 dB ( gain of amplifier PA 2 )$$

$$= - 20 dB$$

This power value of −20 dB can be regarded as sufficiently low.

However, when magnetic coupling occurs, a radio-frequency signal flows along a path starting from the amplifier CA1, going through the amplifier CA2, the interface member 8, the mutual inductance M1, the interface member 7, and the inductor LP1, and ending at the amplifier PA2 and flows into the input terminal of the amplifier PA2. The radio-frequency signal that flows from the output terminal of the amplifier CA2 into the input terminal of the amplifier PA2 is hereinafter referred to as “leaking radio-frequency signal”.

In this case, the power of the radio-frequency signal RF22 outputted from the amplifier PA2 is as follows.

$$+ 10 dB ( gain of amplifier CA 1 )$$

$$+ 10 dB ( gain of amplifier CA 2 )$$

$$- 30 dB ( signal transmission by mutual inductance M 1 )$$

$$+ 10 dB ( gain of amplifier PA 2 )$$

$$= 0 dB$$

The amplifier PA3 is driven by the radio-frequency signal RF22 of 0 dB, and the peak amplifier 13 consequently malfunctions.

### First Feature of First Embodiment

Therefore, the semiconductor device 3 of the first embodiment includes the resistor RP1, which is a first feature. Because of the presence of the resistor RP1, the leaking radio-frequency signal flows along a path starting from the amplifier CA1, going through the amplifier CA2, the interface member 8, the mutual inductance M1, the interface member 7, the resistor RP1, and the inductor LP1, and ending at the amplifier PA2 and flows into the input terminal of the amplifier PA2.

When an attenuation at the resistor RP1 is assumed to be −10 dB, the power of the radio-frequency signal RF22 outputted from the amplifier PA2 is as follows.

$$+ 10 dB ( gain of amplifier CA 1 )$$

$$+ 10 dB ( gain of amplifier CA 2 )$$

$$- 30 dB ( signal transmission by mutual inductance M 1 )$$

$$- 10 dB ( attenuation at resistor RP 1 )$$

$$+ 10 dB ( gain of amplifier PA 2 )$$

$$= - 10 dB$$

This power value of −10 dB of the radio-frequency signal RF22 is very low. Therefore, the semiconductor device 3 can reduce the likelihood that the amplifier PA3 is driven by the leaking radio-frequency signal. Accordingly, the semiconductor device 3 can reduce the likelihood that the peak amplifier 13 malfunctions.

### Second Feature of First Embodiment

The semiconductor device 3 of the first embodiment further includes the capacitor CP1, which is a second feature.

(1)

The capacitor CP1 can further attenuate the radio-frequency signal flowing into the amplifier PA2 through the mutual inductance M1.

The capacitance of the capacitor CP1 is set to a value with which its impedance at the frequency of the radio-frequency input signal RFin and the radio-frequency output signal RFout becomes lower than the resistance of the resistor RP1 to thereby allow a marked attenuation effect to be attained.

The one end of the capacitor CP1 may be connected to a point adjacent to the one end of the resistor RP1 (the node N12) or a point adjacent to the other end of the resistor RP1 (the terminal 3g). However, the one end of the capacitor CP1 is preferably connected to a point adjacent to the one end of the resistor RP1 (the node N12) because of the marked attenuation effect described above and the contribution to matching as described below.

(2)

The capacitor CP1 can simultaneously attain the impedance matching between the amplifier PA1 and the amplifier PA2.

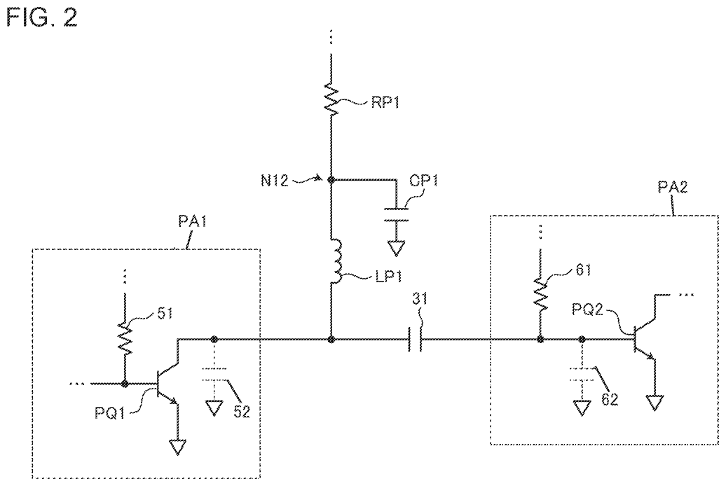

FIG. 2 is a diagram illustrating a part of the peak amplifier of the semiconductor device of the first embodiment.

The amplifier PA1 includes a transistor PQ1. The emitter of the transistor PQ1 is electrically connected to the reference potential. To the base of the transistor PQ1, a base bias current is inputted through a resistor 51. To the collector of the transistor PQ1, power is supplied through the inductor LP1. Between the collector of the transistor PQ1 and the reference potential, a parasitic capacitance 52 is present. The parasitic capacitance 52 can be regarded as a shunt capacitance.

The amplifier PA2 includes a transistor PQ2. The emitter of the transistor PQ2 is electrically connected to the reference potential. To the base of the transistor PQ2, a base bias current is inputted through a resistor 61. Between the base of the transistor PQ2 and the reference potential, a parasitic capacitance 62 is present. The parasitic capacitance 62 can be regarded as a shunt capacitance.

The capacitance of the capacitor CP1 is set to a sufficiently large value to thereby allow a reduction in an AC amplitude at the node N12. Accordingly, the node N12 can be treated as equivalent to the ground potential (ground) in terms of AC. Therefore, the inductor LP1 can be regarded as a shunt inductor.

As a result, resonance occurs between the inductor LP1 and the parasitic capacitance 52, between the inductor LP1 and the parasitic capacitance 62, or between the inductor LP1 and the sum of the parasitic capacitance 52 and the parasitic capacitance 62. Accordingly, the semiconductor device 3 can simultaneously attain the impedance matching between the amplifier PAL and the amplifier PA2.

### Effects

The semiconductor device 3 includes the resistor RP1, which can reduce the likelihood that the leaking radio-frequency signal flows into the amplifier PA2 through the mutual inductance M1.

Accordingly, the semiconductor device 3 can reduce the likelihood that the amplifier PA3 malfunctions and can reduce the likelihood that the peak amplifier 13 consequently malfunctions.

The semiconductor device 3 further includes the capacitor CP1, which can further reduce the likelihood that the leaking radio-frequency signal flows into the amplifier PA2 through the mutual inductance M1.

Accordingly, the semiconductor device 3 can further reduce the likelihood that the amplifier PA3 malfunctions and can further reduce the likelihood that the peak amplifier 13 consequently malfunctions.

Resonance occurs between the inductor LP1 and the parasitic capacitance 52, between the inductor LP1 and the parasitic capacitance 62, or between the inductor LP1 and the sum of the parasitic capacitance 52 and the parasitic capacitance 62.

Accordingly, the semiconductor device 3 can simultaneously attain the impedance matching between the amplifier PA1 and the amplifier PA2.

When a bias current inputted to the amplifier PA1 is smaller than a bias current inputted to the amplifier PA2 subsequent to the amplifier PA1, the problem addressed in the present disclosure is likely to occur (even when a signal of 0 dB is inputted, the signal tends to be amplified). Therefore, the semiconductor device 3 is more useful for such a case.

The semiconductor device 3 is effective when a resistor is not inserted into a power supply path to at least any one amplifier subsequent to the amplifier PAL in the peak amplifier 13. For the subsequent amplifier, the required gain is large and the necessary bias current is likely to become large. Therefore, in the semiconductor device 3, a resistor is not inserted into the power supply path to the subsequent amplifier, which can reduce current consumption.

The resistor RP1 is preferably formed on the semiconductor substrate. Specifically, when the magnetic coupling between the member units is strong, the semiconductor device 3 is likely to attain the effects.

### Others

The resistor RC1 need not be provided. However, to maintain the symmetry between the carrier amplifier 12 and the peak amplifier 13, the resistor RC1 is also desirably provided in addition to the resistor RP1. Similarly, the capacitor CC1 need not be provided. However, to maintain the symmetry between the carrier amplifier 12 and the peak amplifier 13, the capacitor CC1 is also desirably provided in addition to the capacitor CP1. The one end of the capacitor CC1 may be connected to a point adjacent to the one end of the resistor RC1 (the node N11) or a point adjacent to the other end of the resistor RC1 (the terminal 3f).

### Second Embodiment

Among the constituent elements of the second embodiment, a constituent element that is the same as a constituent element of the first embodiment is assigned the same reference numeral, and a description thereof will be omitted.

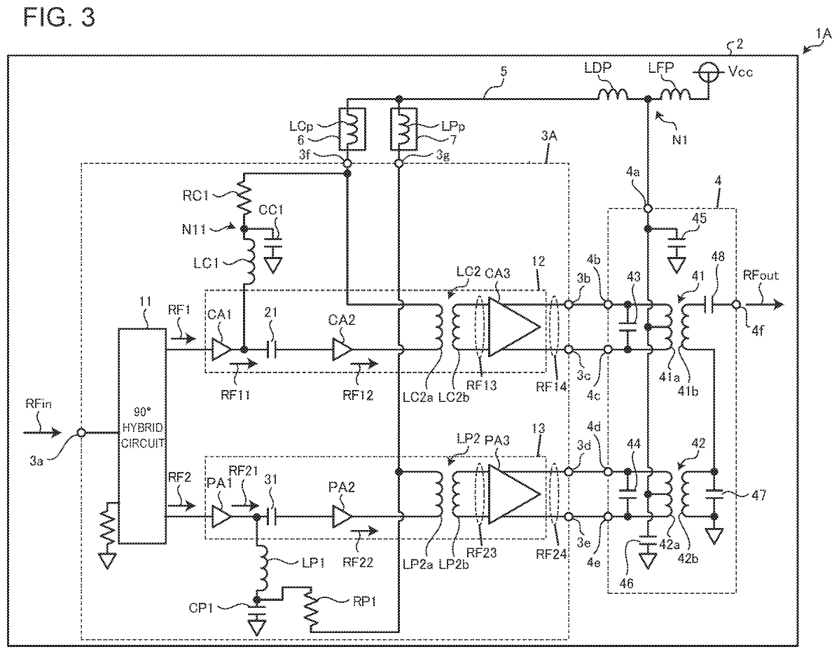

FIG. 3 is a diagram illustrating a configuration of an amplifier module of the second embodiment.

Compared to the amplifier module 1 (see FIG. 1), an amplifier module 1A includes a semiconductor device 3A instead of the semiconductor device 3.

The other end of the primary winding LC2a of the balun LC2 of the semiconductor device 3A is electrically connected to the terminal 3f. That is, the supply voltage Vcc is supplied to the amplifier CA1 in the first stage and the amplifier CA2 in the middle stage in the carrier amplifier 12 through the terminal 3f.

The other end of the primary winding LP2a of the balun LP2 of the semiconductor device 3A is electrically connected to the terminal 3g. That is, the supply voltage Vcc is supplied to the amplifier PAL in the first stage and the amplifier PA2 in the middle stage in the peak amplifier 13 through the terminal 3g.

In the amplifier module 1A, the number of interface members between the semiconductor device 3A and the substrate 2 is smaller than in the amplifier module 1. Therefore, in the amplifier module 1A, the distance between the interface member 6 and the interface member 7 can be made longer than in the amplifier module 1. Therefore, in the amplifier module 1A, the magnetic coupling between the interface member 6 and the interface member 7 can be made weaker.

However, even in an ideal state in which the magnetic coupling between the interface member 6 and the interface member 7 does not occur at all, the parasitic inductance LDP is present in the wiring line 5. Therefore, when the resistor RP1 is not provided, a leaking radio-frequency signal flows along a path starting from the amplifier CA1, going through the amplifier CA2, the interface member 6, the wiring line 5, the interface member 7, and the inductor LP1, and ending at the amplifier PA2 and flows into the input terminal of the amplifier PA2. Accordingly, the amplifier PA3 is driven by the leaking radio-frequency signal, and the peak amplifier 13 consequently malfunctions.

Therefore, the semiconductor device 3A includes the resistor RP1. Because of the presence of the resistor RP1, a leaking radio-frequency signal flows along a path starting from the amplifier CA1, going through the amplifier CA2, the interface member 6, the wiring line 5, the interface member 7, the resistor RP1, and the inductor LP1, and ending at the amplifier PA2 and flows into the input terminal of the amplifier PA2. This leaking radio-frequency signal is attenuated by the resistor RP1.

Therefore, the semiconductor device 3A can reduce the likelihood that the amplifier PA3 is driven by the leaking radio-frequency signal. Accordingly, the semiconductor device 3A can reduce the likelihood that the peak amplifier 13 malfunctions.

### Third Embodiment

Among the constituent elements of a third embodiment, a constituent element that is the same as a constituent element of the other embodiments is assigned the same reference numeral, and a description thereof will be omitted.

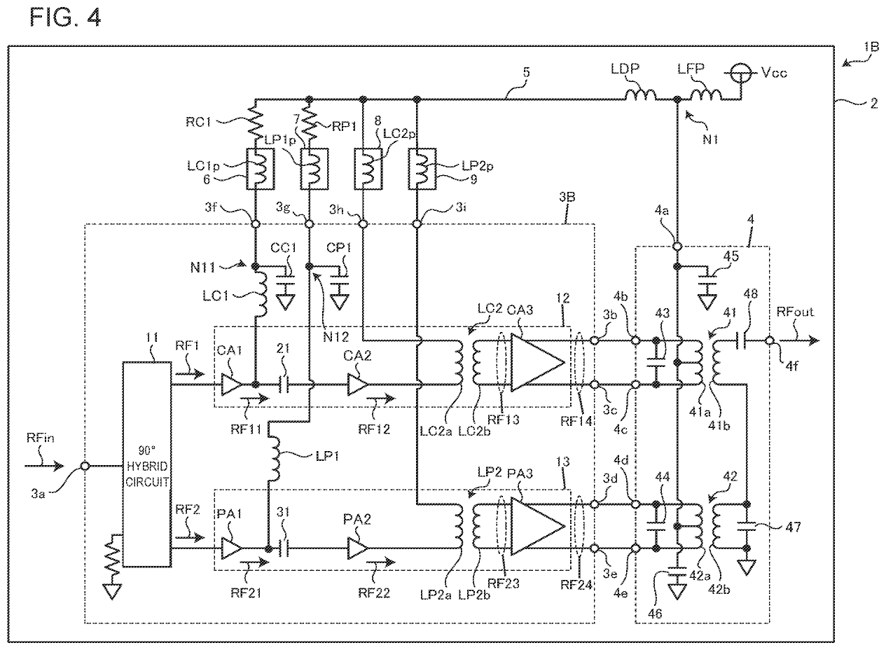

FIG. 4 is a diagram illustrating a configuration of an amplifier module of the third embodiment.

Compared to the amplifier module 1 (see FIG. 1), an amplifier module 1B includes a semiconductor device 3B instead of the semiconductor device 3.

Compared to the semiconductor device 3, the semiconductor device 3B does not include the resistor RC1 or RP1. Instead, the resistor RC1 is provided between the interface member 6 and the wiring line 5. The resistor RP1 is provided between the interface member 7 and the wiring line 5. That is, the resistors RC1 and RP1 are provided on the substrate 2.

Even when the mutual inductance M1 (see FIG. 1) between the interface member 7 and the interface member 8 is not present or is small, the parasitic inductance LDP is present in the wiring line 5 as described in the second embodiment. Therefore, when the resistor RP1 is not provided, a leaking radio-frequency signal flows along a path starting from the amplifier CA1, going through the amplifier CA2, the interface member 8, the wiring line 5, the interface member 7, and the inductor LP1, and ending at the amplifier PA2 and flows into the input terminal of the amplifier PA2. Accordingly, the amplifier PA3 is driven by the leaking radio-frequency signal, and the peak amplifier 13 consequently malfunctions.

Therefore, the amplifier module 1B includes the resistor RP1. Because of the presence of the resistor RP1, a leaking radio-frequency signal flows along a path starting from the amplifier CA1, going through the amplifier CA2, the interface member 8, the wiring line 5, the resistor RP1, the interface member 7, and the inductor LP1, and ending at the amplifier PA2 and flows into the input terminal of the amplifier PA2. This leaking radio-frequency signal is attenuated by the resistor RP1.

Therefore, the amplifier module 1B can reduce the likelihood that the amplifier PA3 is driven by the leaking radio-frequency signal. Accordingly, the amplifier module 1B can reduce the likelihood that the peak amplifier 13 malfunctions.

### Example Configurations of Present Disclosure

The present disclosure can also employ the following configurations.

(1)

A Doherty amplifier including: a carrier amplifier that is formed on a semiconductor substrate and that includes amplifiers in one or more stages including a first amplifier in one stage to which a first bias current is inputted; a peak amplifier that is formed on the semiconductor substrate and that includes amplifiers in two or more stages including a second amplifier to which a second bias current smaller than the first bias current is inputted; and a first resistor that is inserted in series into a power supply path to the second amplifier.

(2)

The Doherty amplifier according to (1) above, further including: a first capacitor that is formed on the semiconductor substrate, that has one end electrically connected to the power supply path to the second amplifier, and that has another end electrically connected to a reference potential.

(3)

The Doherty amplifier according to (2) above, in which the first capacitor has a capacitance with which an impedance of the first capacitor at a frequency of a radio-frequency signal becomes lower than a resistance of the first resistor.

(4)

The Doherty amplifier according to (2) or (3) above, in which the one end of the first capacitor is electrically connected to a point closer to the second amplifier than the first resistor is.

(5)

The Doherty amplifier according to any one of (2) to (4) above, further including: a first inductor that is inserted in series between the one end of the first resistor and the second amplifier.

(6)

The Doherty amplifier according to any one of (1) to (5) above, in which the second bias current is smaller than a third bias current that is inputted to a third amplifier subsequent to the second amplifier.

(7)

The Doherty amplifier according to (6) above, in which the third bias current is equal to a fourth bias current that is inputted to a fourth amplifier subsequent to the first amplifier.

(8)

The Doherty amplifier according to any one of (1) to (7) above, in which a resistor is not inserted into a power supply path to at least any one amplifier, among the amplifiers, subsequent to the second amplifier in the peak amplifier.

(9)

The Doherty amplifier according to any one of (1) to (8) above, in which the first resistor is formed on the semiconductor substrate.

(10)

The Doherty amplifier according to any one of (1) to (9) above, in which the number of stages in the carrier amplifier and the number of stages in the peak amplifier are equal to each other, and the second amplifier is in a stage that is the same as the one stage.

Note that the embodiments described above are intended to facilitate understanding of the present disclosure and are not intended to interpret the present disclosure in a limited manner. The present disclosure can be changed/improved without departing from the gist thereof, and the present disclosure includes its equivalents.

What is claimed is:

1. A Doherty amplifier comprising:
a carrier amplifier that is on a semiconductor substrate and that comprises a first plurality of amplifiers in one or more stages, the first plurality of amplifiers comprising a first amplifier to which a first bias current is input;
a peak amplifier that is on the semiconductor substrate and that comprises a second plurality of amplifiers in two or more stages, the second plurality of amplifiers comprising a second amplifier to which a second bias current smaller than the first bias current is input; and
a first resistor that is in a power supply path of the second amplifier.

2. The Doherty amplifier according to claim 1, further comprising:
a first capacitor that is on the semiconductor substrate, that has a first end electrically connected to the power supply path, and that has a second end electrically connected to a reference potential.

3. The Doherty amplifier according to claim 2, wherein the first capacitor has a capacitance with which an impedance of the first capacitor at a frequency of a radio-frequency signal is lower than a resistance of the first resistor.

4. The Doherty amplifier according to claim 2, wherein the first end of the first capacitor is electrically connected to a node closer to the second amplifier than the first resistor.

5. The Doherty amplifier according to claim 2, further comprising:
a first inductor that is connected in series between the first resistor and the second amplifier.

6. The Doherty amplifier according to claim 1, wherein the second bias current is smaller than a third bias current that is input to a third amplifier subsequent to the second amplifier.

7. The Doherty amplifier according to claim 6, wherein the third bias current is equal to a fourth bias current that is input to a fourth amplifier subsequent to the first amplifier.

8. The Doherty amplifier according to claim 1, wherein there is no resistor in a power supply path of one of the second plurality of amplifiers subsequent to the second amplifier.

9. The Doherty amplifier according to claim 1, wherein the first resistor is on the semiconductor substrate.

10. The Doherty amplifier according to claim 1,
wherein a number of stages in the carrier amplifier and a number of stages in the peak amplifier are equal to each other, and
wherein the second amplifier is in a same stage as the first amplifier.
